(19) United States
(12) Patent Application Publication
(10) Pub. No.: US 2016/0177442 A1
(43) Pub. Date: Jun. 23, 2016

(54) GAS SHIELD FOR VAPOR DEPOSITION

(71) Applicant: Ervin Beloni, Clifton, NJ (US)

(72) Inventor: Ervin Beloni, Clifton, NJ (US)

(21) Appl. No.: 14/957,021

(22) Filed: Dec. 2, 2015

Related U.S. Application Data
(60) Provisional application No. 62/093,794, filed on Dec. 18, 2014.

(51) Int. Cl. C23C 16/455

(52) U.S. Cl. CPC C23C 16/455

(57) ABSTRACT

A gas shield, assembly and methods for use in chemical vapor deposition processes are disclosed. In one example, the gas shield can include a ring portion and a conical portion. The ring portion can be adapted to receive a substrate. The conical portion can be coupled to the ring portion and can have a plurality of holes therethrough. The plurality of holes can be configured to allow a precursor gas to communicate with the substrate.

### CLAIM OF PRIORITY

This application claims the benefit of U.S. Provisional Patent Application Ser. No. 62/093,794, filed on Dec. 18, 2014, the benefit of priority of which is claimed hereby, and which is incorporated by reference herein in its entirety.

### TECHNICAL FIELD

The present application relates to chemical vapor deposition processes, and more particularly, to a conically shaped gas shield used in chemical vapor deposition processes.

### BACKGROUND

The need for cancellous bone substitute and/or cell and tissue receptive material is significant. Bone ingrowth into the voids of a porous material provides ideal skeletal fixation for permanent implants used for the replacement of bone segments damaged or lost due to any number of reasons, or for joint prostheses in some instances. Biological compatibility, intimate contact with the surrounding bone, and adequate stability during the early period of bone ingrowth have been identified as important requirements, along with proper porosity. The optimal porous material should have good crack resistance, particularly under impact, and compliance comparable to that of bone. The material should also make the manufacture of implants of precise dimensions easy, and permit the fabrication of either thick or thin coatings on load-bearing cores.

Processes for forming porous bio-compatible materials are known. In one such process, reticulated open cell carbon foam is infiltrated with a metal or metal alloy (e.g., tantalum, tantalum alloys, etc.) by a chemical vapor deposition (CVD) process. The resulting lightweight, strong, porous structure, mimics the microstructure of natural cancellous bone, and acts as a matrix for the incorporation of bone or reception of cells and tissue. Although this technique has proven to be very effective, in some instances, deposition of the metal can be uneven. Thus, portions of the carbon foam can be over-densified or under-densified relative to a desired density. In some cases these portions are removed necessitating additional processing steps and time.

### OVERVIEW

The present inventor recognizes, among other things, an opportunity to distribute gas more uniformly during the CVD process. More particularly, the present inventor recognizes that a conically shaped gas shield having a plurality of holes can act to impinge and distribute precursor gases more uniformly such that precursor gases enter an object (e.g., reticulated open cell carbon foam disk) adjacent the gas shield at a more uniform velocity that results in a more uniform density profile within and along the object both radially and axially. Although described in reference to CVD processes that utilize a metal or metal alloy (e.g., tantalum) in a precursor gas and a reticulated open cell carbon foam substrate, the conically shaped gas shield can be utilized for other CVD processes where a more uniform distribution of precursor gas and a more uniform density profile can be desirable.

To further illustrate the gas shield, assemblies and methods disclosed herein, a non-limiting list of examples is provided here:

In Example 1, a gas shield for use in a chemical vapor deposition process is disclosed. The shield can comprise a ring portion adapted to receive a substrate and a conical portion coupled to the ring portion. The conical portion can have a plurality of holes therethrough that are configured to allow a precursor gas to communicate with the substrate.

In Example 2, the gas shield of Example 1, wherein the substrate can comprise a reticulated carbon foam.

In Example 3, the gas shield any one or any combination of Examples 1 to 2, wherein each hole of the plurality of holes can have an area of between about 0.02% and about 0.3% of a surface area of the conical portion of the gas shield.

In Example 4, the gas shield any one or any combination of Examples 1 to 3, wherein a total area of the plurality of holes can be between about 10% and about 40% of a surface area of the conical portion.

In Example 5, the gas shield any one or any combination of Examples 1 to 4, wherein the conical portion can have an angle relative to a plane extending along an axial end of the ring portion of between about 7.5° and about 70°.

In Example 6, the gas shield any one or any combination of Examples 1 to 5, wherein the plurality of holes can be arranged as concentric rings about a solid tip region of the conical portion.

In Example 7, the gas shield any one or any combination of Examples 1 to 6, wherein both the ring portion and the conical portion can comprise graphite and both the ring portion and the conical portion can have a wall thickness of less than 1 inch.

In Example 8, an assembly for use in a chemical vapor deposition process is disclosed. The assembly can comprise a furnace, a gas shield, and a substrate. The furnace can be adapted to receive a precursor gas therein. The gas shield can be disposed within the furnace in a flow path of the precursor gas. The substrate can be disposed adjacent the conical portion and can communicate with the inner cavity. The gas shield can have a conical portion configured to direct the precursor gas along an outer surface thereof and can have a plurality of holes therethrough that are configured to allow the precursor gas to enter an inner cavity defined by the conical portion. The substrate can be configured to receive a thin film deposition from the precursor gas.

In Example 9, the assembly of Example 8, wherein the gas shield can have a ring portion coupled to the conical portion and adapted to receive the substrate.

In Example 10, the assembly any one or any combination of Examples 8 to 9, wherein the substrate can comprise a reticulated carbon foam.

In Example 11, the assembly any one or any combination of Examples 8 to 10, wherein the precursor gas can include a tantalum or tantalum alloy.

In Example 12, the assembly any one or any combination of Examples 8 to 11, wherein each hole of the plurality of holes can have an area of between about 0.025% and about 0.3% of a surface area of the conical portion of the gas shield.

In Example 13, the assembly any one or any combination of Examples 8 to 12, wherein a total area of the plurality of holes can be between about 10% and about 40% of a surface area of the conical portion.

In Example 14, the assembly any one or any combination of Examples 8 to 13, wherein the conical portion has an angle relative to a plane extending along an axial end of the ring portion of between about 7.5° and about 70°.

In Example 15, the assembly any one or any combination of Examples 8 to 14, wherein the plurality of holes can be arranged as concentric rings about a solid tip region of the conical portion.

In Example 16, a chemical vapor deposition method is disclosed. The method can comprise flowing a precursor gas in a hot walled furnace, directing the precursor gas with a gas shield having a conical portion with a plurality of holes therethrough, and positioning a substrate adjacent the conical portion of the gas shield to receive the precursor gas passing through the plurality of holes.

In Example 17, the method of Example 16, wherein the substrate can comprise a reticulated carbon foam having a porosity of between 55% and 90%.

In Example 18, the method any one or any combination of Examples 16 to 17, wherein the precursor gas can include a tantalum or tantalum alloy.

In Example 19, the method any one or any combination of Examples 16 to 18, wherein a total area of the plurality of holes can be between about 10% and about 40% of a surface area of the conical portion.

In Example 20, the method any one or any combination of Examples 16 to 19, wherein the plurality of holes can be arranged as concentric rings about a tip of the conical portion.

In Example 21, the gas shield, assembly, or method of any one or any combination of Examples 1-20 can optionally be configured such that all elements or options recited are available to use or select from.

These and other examples and features of the present apparatuses and methods will be set forth in part in the following Detailed Description. This Overview is intended to provide non-limiting examples of the present subject matter—it is not intended to provide an exclusive or exhaustive explanation. The Detailed Description below is included to provide further information about the present apparatus, systems and methods.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 a perspective view of a porous metal structure, according to an example of the present disclosure.

FIG. 2 is a schematic illustration of a CVD process used to form the porous metal structure, according to an example of the present disclosure.

FIG. 2A is an enlargement of a furnace and other components illustrated in FIG. 2.

FIG. 3 is a perspective view of a conically shaped gas shield, according to an example of the present disclosure.

FIG. 3A is a plan view of an outer surface of the conically shaped gas shield of FIG. 3.

FIG. 3B is a cross-sectional view of the conically shaped gas shield of FIG. 3.

FIG. 4 is a perspective view of a conically shaped gas shield, according to another example of the present disclosure.

FIG. 5 is a perspective view of a conically shaped gas shield, according to another example of the present disclosure.

FIG. 6A is a plot of gas velocity v. radial position along the substrate as calculated at multiple axial positions (top face (A), middle (B), and bottom face (C)) within the substrate, wherein the example of FIG. 6A utilizes a conically shaped gas shield.

FIG. 6B is a plot of gas velocity v. radial position along the substrate as calculated at multiple axial positions (top face (A), middle (B), and bottom face (C)) within the substrate, wherein the example of FIG. 6B does not utilize the conically shaped gas shield of FIG. 6A.

FIG. 7A is a plot of normalized density v. radial position for several axial positions (top face (A), middle (B), and bottom face (C)) within the substrate, wherein the example of FIG. 7A utilizes the conically shaped gas shield of FIG. 6A.

FIG. 7B is a plot of normalized density v. radial position for several axial positions (top face (A), middle (B), and bottom face (C)) within the substrate, wherein the example of FIG. 7B does not utilize the conically shaped gas shield of FIGS. 6A and 7A.

FIG. 8 is a method according to an example of the present disclosure.

### DETAILED DESCRIPTION

The present application relates to conically shaped gas shields and methods for their use in CVD processes. The conically shaped gas shield can have a plurality of holes therein that allow a precursor gas to access a substrate. Individually each hole can have an area of between about 0.02% to about 0.3% of the surface area of the conical portion of the gas shield in some instances. In some cases, the total area of the holes can be about 10% to about 40% of a surface area of the conical portion of the gas shield. According to further examples, the conical portion can have an angle relative to a plane extending along an axial end of the ring portion of between about 7.5° and about 70°.

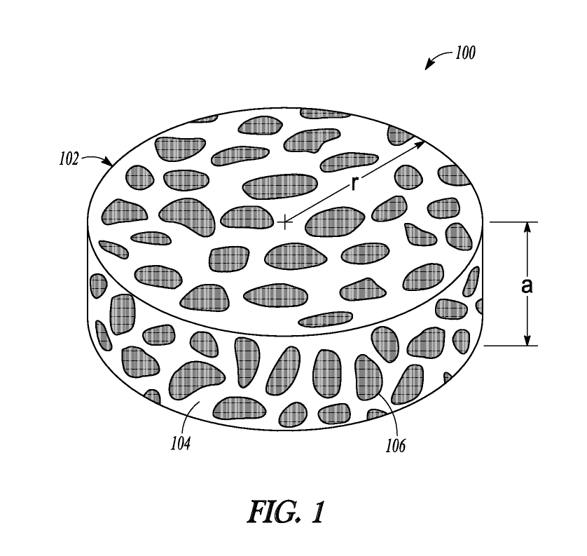

FIG. 1 illustrates an exemplary configuration of porous metal structure 100. As illustrated in FIG. 1, the shapeable porous implant 100 can comprise a disk 102 of highly porous metal material having a radius r and an axial thickness a. The porosity of the porous metal material can be between 55% and 90%, although other porosities are also contemplated. A size and dimensions of the porous metal structure 100 can be determined based on the desired size of the objects (orthopedic implants, etc.) created therefrom among other factors. Because the disk 102 can have a porous structure, the disk 102 can promote bone ingrowth and fusion in some circumstances, as further described below.

The porous metal structure 100 can include a plurality of ligaments 104 defining a plurality of highly interconnected, three-dimensional open spaces or pores 106 therebetween. The porous metal structure can incorporate one or more of a variety of biocompatible metals. Such structures are particularly suited for contacting bone and soft tissue, and in this regard, can be useful as a bone substitute and as cell and tissue receptive material, for example, by allowing tissue to grow into the porous structure over time to enhance fixation (e.g., osseointegration) between the structure and surrounding bodily structures. According to certain examples of the present disclosure, the porous metal structure 100 can have a porosity as low as 55%, 65%, or 75% or as high as 80%, 85%, or 90%, or within any range defined between any pair of the foregoing values. As will be discussed in further detail, the porous metal structure 100 can be formed from a reticulated vitreous carbon foam substrate which is infiltrated and coated with a biocompatible metal, such as tantalum, by a CVD process. Such a CVD process is disclosed in detail in U.S. Pat. No. 5,282,861 and in Levine, B.R., et al., “Experimental and Clinical Performance of Porous Tantalum in Orthopedic Surgery”, Biomaterials 27 (2006) 4671-4681, the disclosures of which are expressly incorporated herein by reference. In addition to tantalum, other biocompatible metals may also be used in the formation of a highly porous metal structure such as titanium, a titanium alloy, cobalt chromium, cobalt chromium molybdenum, tantalum, a tantalum alloy, niobium, or alloys of tantalum and niobium with one another or with other metals. It is also within the scope of the present disclosure for the porous metal structure 100 to be in the form of a fiber metal pad or a sintered metal layer, such as a Cancellous-Structured Titanium™ (CSTi™) layer. CSTi™ porous layers are manufactured by Zimmer, Inc., of Warsaw, Ind. Cancellous-Structured Titanium™ and CSTi™ are trademarks of Zimmer, Inc.

Generally, the porous metal structure 100 will include a large plurality of metallic ligaments 104 defining open voids 106 (e.g., pores) or channels therebetween. The open spaces between the ligaments form a matrix of continuous channels having few or no dead ends, such that growth of soft tissue and/or bone through open porous metal is substantially uninhibited. Thus, the porous metal structure 100 can provide a lightweight, strong porous structure which is substantially uniform and consistent in composition, and provides a matrix (e.g., closely resembling the structure of natural cancellous bone) into which soft tissue and bone may grow to provide fixation of the implant to surrounding bodily structures.

The porous metal structure 100 may also be fabricated such that it comprises a variety of densities in order to selectively tailor the structure for particular orthopedic applications. In particular, the porous metal structure 100 may be fabricated to virtually any desired density, porosity, and pore size (e.g., pore diameter), and can thus be matched with the surrounding natural tissue in order to provide an improved matrix for tissue ingrowth and mineralization. According to certain examples, the porous metal structure 100 can be fabricated to have a substantially uniform porosity, density, and/or void (pore) size throughout, or to comprise at least one of pore size, porosity, and/or density being varied within the structure. For example, the porous metal structure 100 may have a different pore size and/or porosity at different regions, layers, and surfaces of the structure. The ability to selectively tailor the structural properties of the porous metal structure 100, for example, enables tailoring of the structure for distributing stress loads throughout the surrounding tissue and promoting specific tissue ingrown within the porous metal structure 100.

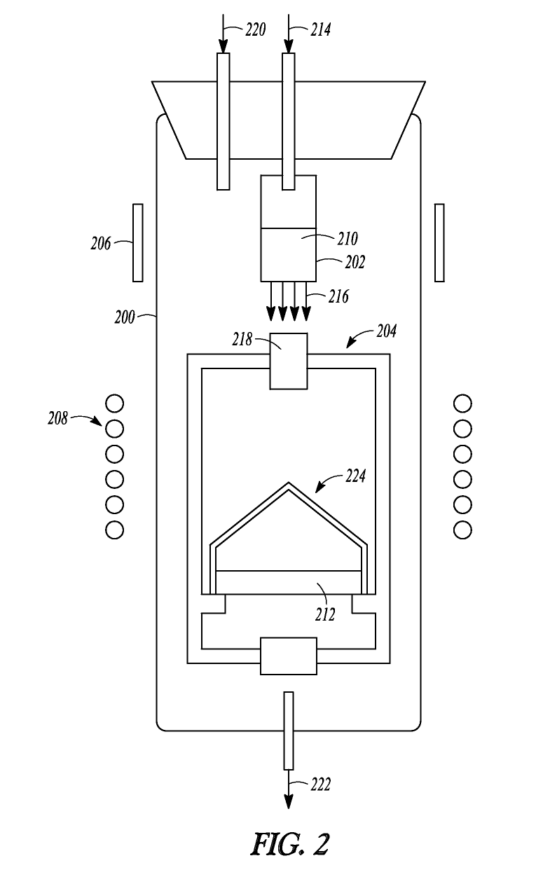

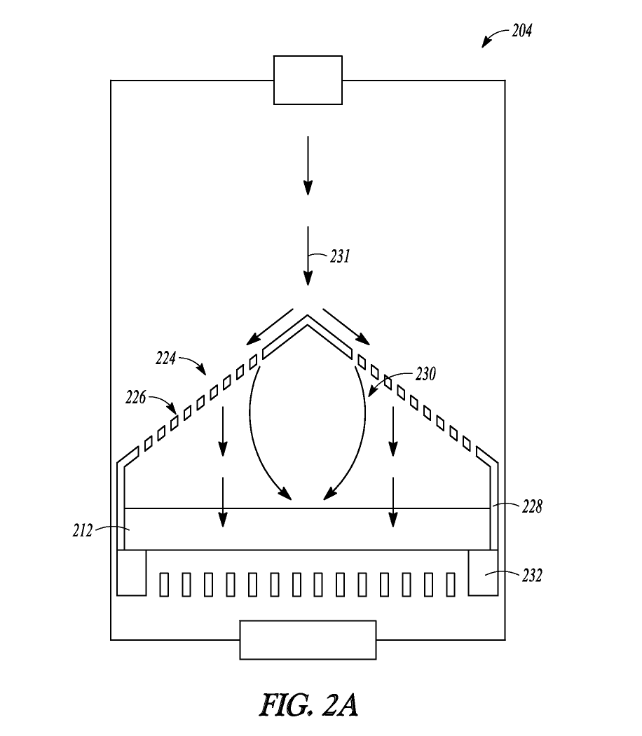

FIG. 2 illustrates an apparatus for depositing a metal, such as tantalum, on a substrate 212 (e.g., carbon foam). A reaction chamber 200 encloses a chlorination chamber 202 and a hot wall furnace 204. A resistance heater 206 can surround the chamber 200 adjacent the chlorination chamber 202 and an induction heating coil 208 can surround the reaction chamber 200 to heat the hot wall furnace 204. FIG. 2A provides an enlargement of the hot wall furnace 204 illustrating the substrate 212 and a conically shaped gas shield 224.

As shown in FIG. 2, a metal 210 can be located within the chlorination chamber 202 and the substrate 212 can be positioned within the hot wall furnace 204. Chlorine gas, as shown by arrow 214 is injected into the chlorination chamber 202 to react with the metal 210 to form a gas 216. The gas 216 can comprise tantalum chloride, if tantalum comprises the metal 204 selected. The tantalum chloride can mix with hydrogen injected into the chamber 200 as shown by arrow 220, the mixture, comprising a precursor gas, can then pass through an opening 218 in the hot wall furnace 204. The precursor gas is heated within the hot wall furnace to a temperature of about 1100° C. to produce a surface reaction. If tantalum is utilized, the surface reaction can be characterized by the following formula: TaCl₅+(5/2)H₂→Ta+5HCl. The surface reaction deposits the metal on the substrate 212 to produce a thin film over the individual ligaments of the substrate. Thus, the porous metal structure 100 of FIG. 1 can be formed. The hydrogen chloride is then exhausted as shown by arrow 222.

FIG. 2A illustrates the hot wall furnace 204 and shows the conically shaped gas shield 224 disposed adjacent the substrate 212. The gas shield 224 can include a conical portion 226 and a ring portion 228. The gas shield 224 can comprise a thin walled structure with a hollow inner cavity 230. According to one example, the gas shield 224 can be comprised of graphite and can have a wall thickness of about 0.25 inches in both the conical portion 226 and the ring portion 228. The conical portion 226 can be coupled to the ring portion 228. In some cases, the conical portion 226 and the ring portion 228 can be integrally formed as a monolithic structure so as to comprise a single component.

In the example of FIG. 2A, both the substrate 212 and the gas shield 224 are mounted in a retention structure 232. In some cases, the substrate 212 can comprise a disk, as previously discussed. The substrate 212 can be disposed within the gas shield 224. In particular, the substrate 212 can be received within the ring portion 228 so as to have a periphery surrounded thereby. According to one example, the substrate 212 can have a diameter of about 12 inches and an axial thickness of about 1.5 inches. Similarly, the ring portion 228 can have an inner diameter of slightly more than 12 inches so as to closely interface with the substrate 212. However, in other examples, the substrate 212 can have different diameters and/or axial thicknesses. Similarly, the ring portion 228 can have an inner diameter of slightly more than the diameter of the substrate 212 so as to closely interface with the substrate 212.

As illustrated by arrows 231, the precursor gas can impinge on the outer surface of the conical portion 226 and be spread out radially along the outer surface of the conical portion 226. The precursor gas can pass through a plurality of holes in the conical portion 226 to enter the inner cavity 230 defined by the conical portion 226. The configuration of the gas shield 224 with the conically shaped outer surface and plurality of holes can manipulate the flow field of the precursor gas such that the precursor gas comes into contact with the substrate 212 at a more uniform velocity. The more uniform velocity can result in a more uniform deposition profile inside the substrate 212 as the precursor gas residence time throughout the substrate 212 is more uniform. Since the precursor gas residence time can be more uniform, all portions of the substrate 212 can have a similar deposition rate, and therefore, achieve a more uniform weight during the CVD deposition cycle.

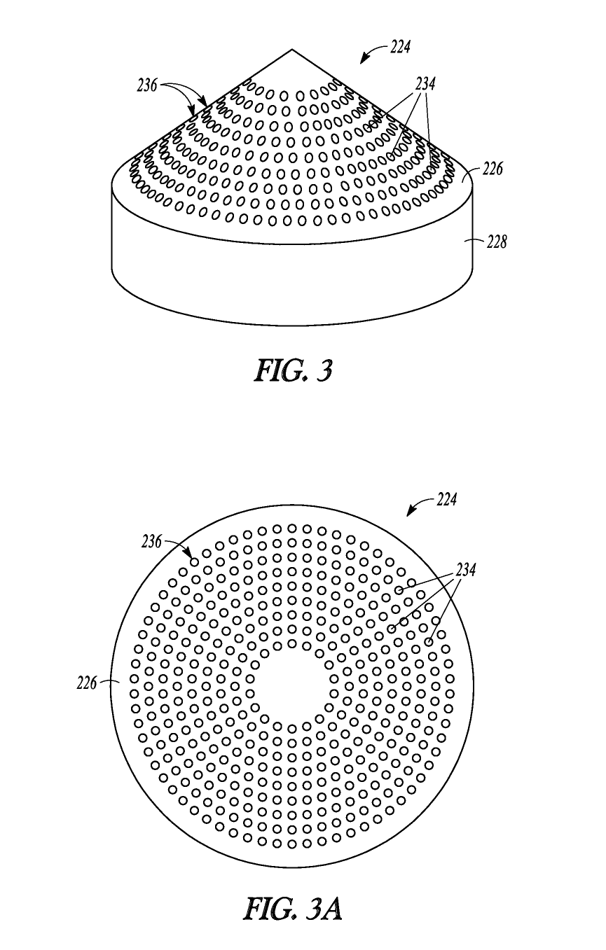

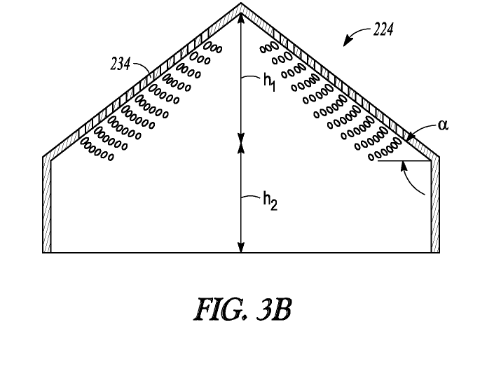

FIGS. 3, 3A and 3B illustrate an example of the gas shield 224. As discussed, the gas shield 224 can include the conical portion 226 and the ring portion 228. The conical portion 226 can have a plurality of holes 234. The holes 234 can be arranged in a concentric manner about a tip of the cone comprising a plurality of rings 236.

According to the example of FIGS. 3 and 3A, the rings 236 can comprise 9 rings, each disposed at a different radial distance around a tip of the cone. The tip of the cone can comprise a region without holes therein. The size of this tip region can vary from case to case. In one example, the tip region can extend about 1.375 inches down the outer surface of the conical portion 226 from the tip prior to reaching the first ring of holes. In some instances, each ring can have six more holes than the adjacent radially inward ring. Thus, in some cases, the ring disposed adjacent the innermost tip of the cone can comprise 18 holes, a second ring adjacent the inner ring can have 24 holes, a third ring adjacent the second ring can comprise 30 holes, etc. Thus, conical portion 226 can have 378 holes therethrough according to one example. In some cases, each of the holes 234 can have a diameter of about 0.25 inches and the outer diameter of the ring portion 228 (and conical portion 226) can be about 12.5 inches. Thus, individually each hole can have an area of between about 0.04% of the surface area of the conical portion 226 of the gas shield 224. In some cases, the total area of the holes 234 can be about 15.1% of a surface area of the conical portion 226 of the gas shield 224.

As shown in the cross-section of FIG. 3B, the axial height h₁ of the conical portion 226 can be about 5 inches while the axial height h₂ of the ring portion 228 can be about 3 inches. As shown in FIG. 3B, the conical portion 226 can have an angle a of about 40° relative to a plane extending along an axial end of the ring portion 228. According to further examples, the angle a of the conical portion relative to the plane extending along an axial end of the ring portion 228 can be between about 7.5° and about 70°. Although an example diameter of the holes of 0.25 inches has been provided, other hole diameters are contemplated and can range from about 0.1 inches to about 1.0 inches, for example.

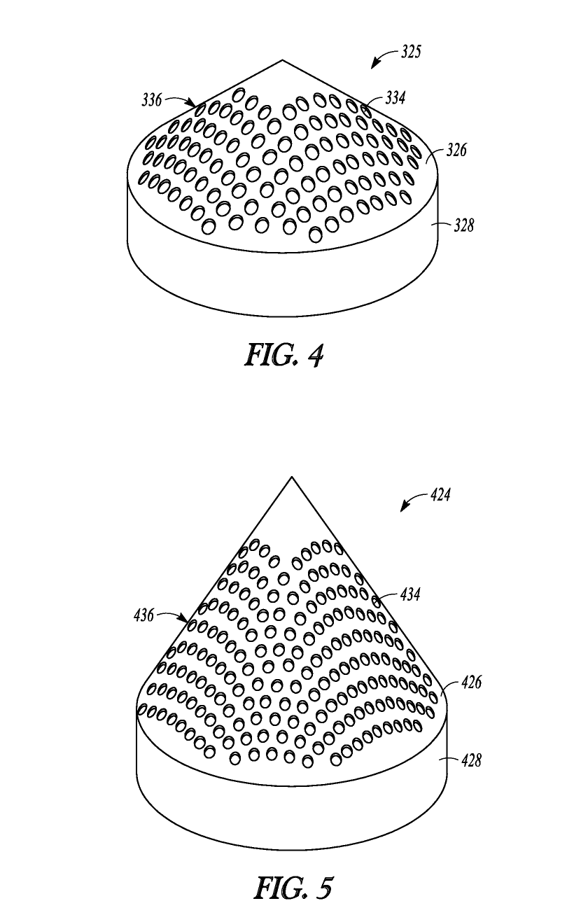

FIG. 4 illustrates another example of a gas shield 324 having a conical portion 326 and a ring portion 328. The conical portion 326 can have a plurality of holes 334. The holes 334 can be arranged in a plurality of rows 336 rather than the ring pattern of FIG. 3. Thus, conical portion 326 can have 168 holes therethrough.

According to one example, each of the holes 334 can have a diameter of about 0.50 inches and the outer diameter of the ring portion 328 (and conical portion 326) can be about 12.5 inches. Thus, individually each hole can have an area of between about 0.2% of the surface area of the conical portion 326 of the gas shield 324. In some cases, the total area of the holes 334 can be about 34% of a surface area of the conical portion of the gas shield 324. In FIG. 4, the axial heights of the conical portion 326 and the ring portion 324 can be the same as provided in the example of FIGS. 3 and 3A and illustrated in FIG. 3B. Similarly, the conical portion 326 can have the same angle relative to the plane extending along an axial end of the ring portion 328 as provided in the example of FIGS. 3 and 3A and shown in FIG. 3B.

FIG. 5 illustrates yet another example of a gas shield 424 having a conical portion 426 and a ring portion 428. The conical portion 426 can have a plurality of holes 434. The holes 434 can be arranged in a plurality of rows 436 similar to the embodiment of FIG. 4.

According to the illustrated example, each of the holes 434 can have a diameter of about 0.25 inches and the outer diameter of the ring portion 428 (and conical portion 426) can be about 12.5 inches. In FIG. 5, the axial height of the conical portion 426 can be about 7 inches while the axial height of the ring portion 428 can be about 3 inches. As shown in FIG. 5, the conical portion 426 can have an angle a (see FIG. 3B) of about 60° relative to a plane that extends along an axial end of the ring portion 428. It should be recognized that the height of the gas shield is not limited within the furnace, and thus, the conical portion can have any desired height and/or angle relative to the plane extending along an axial end of the ring portion 428.

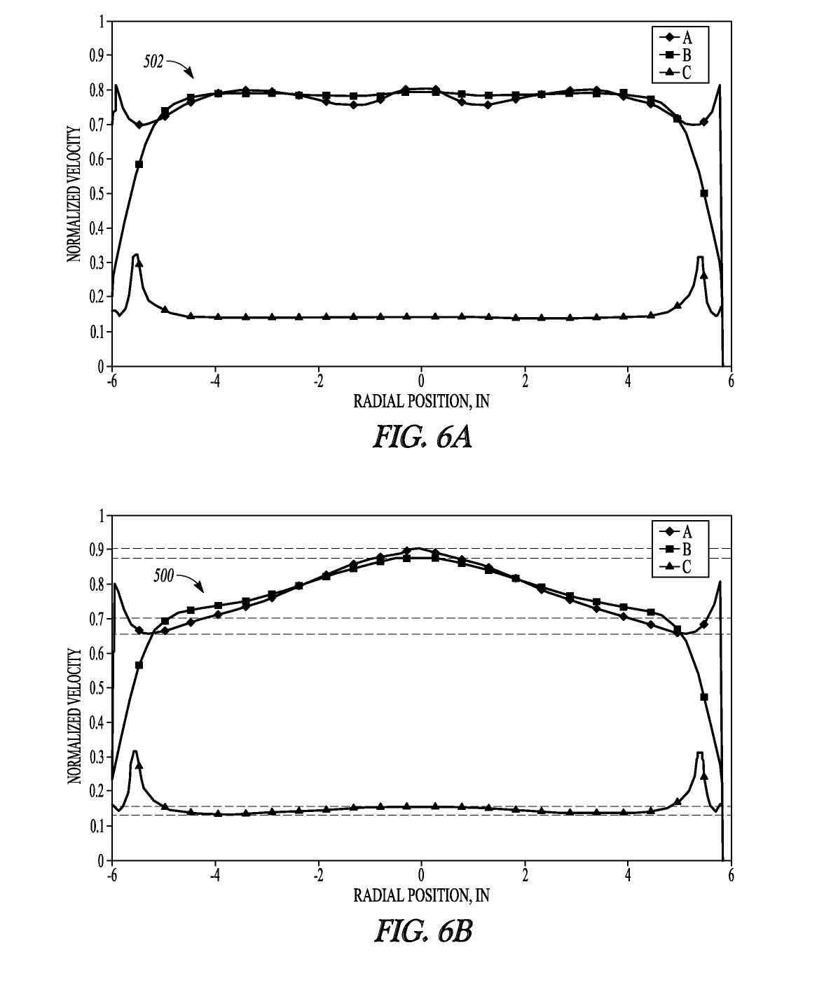

FIGS. 6A and 6B provide examples of gas velocity plotted v. radial position of the substrate. The velocities were calculated at multiple axial positions (top face (A), middle (B), and bottom face (C)) within the substrate. FIG. 6B shows a typical velocity profile 500 without use of a conically shaped gas shield. As shown in FIG. 6B, the velocities at the top and middle of the substrate can have a degree of non-uniformity with relatively higher velocities at a center (as calculated radially) of the substrate relative to the velocities toward the outer radius. FIG. 6A shows a velocity profile 502 with use of the conically shaped gas shield. As shown in FIG. 6A, the velocity at the top and middle of the substrate can have a greater degree of uniformity with the velocities at a center (as measured radially) of the substrate similar to the velocities toward the outer radius.

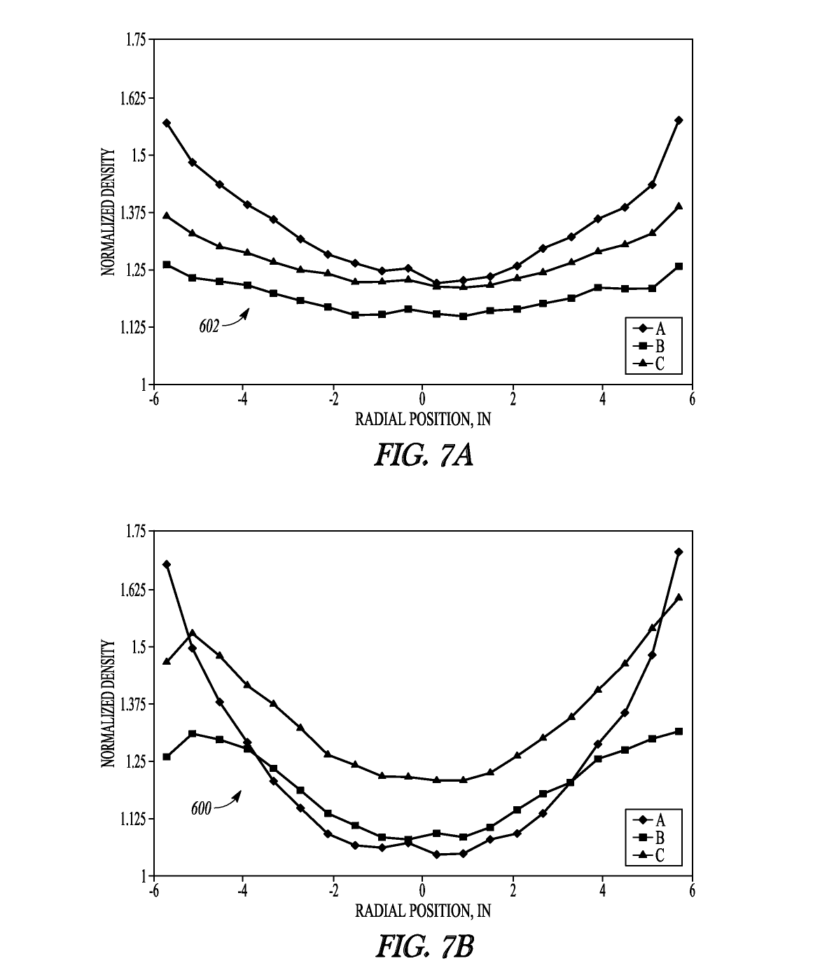

FIGS. 7A and 7B provide examples of normalized density plotted v. radial position for several axial positions (top face (A), middle (B), and bottom face (C)) within the substrate. FIG. 7B shows typical normalized density profiles 600 for different axial positions (top face (A), middle (B), and bottom face (C)) within the substrate produced without the use of the conically shaped gas shield. As shown in FIG. 7B, the relative densities at the outer radius of each substrate can have a degree of non-uniformity, with overall higher relative densities at these locations as compared to the relative densities at a center (as measured radially) of the substrate. FIG. 7A shows normalized density 602 plotted v. radial position for the same several axial positions (top face (A), middle (B), and bottom face (C)) within the substrate with use of the conically shaped gas shield. As shown in FIG. 7A, the relative densities at the outer radius of the substrate can have a greater degree of uniformity as compared to the relative densities at a center (as measured radially). Indeed, data indicates axial variation can be reduced by about 30% by use of the conically shaped gas shield. Additionally, data indicates that radial variation can be reduced by about 50% by use of the conically shaped gas shield.

Further analysis was performed and tends to indicate that use of the conically shaped gas shield during CVD can improve other desirable characteristics including deposition efficiency and mechanical strength. It should also be recognized that use of the conically shaped gas shield can reduce the number of substrates that do not meet specification, thereby reducing the number of rejects and the cost of production.

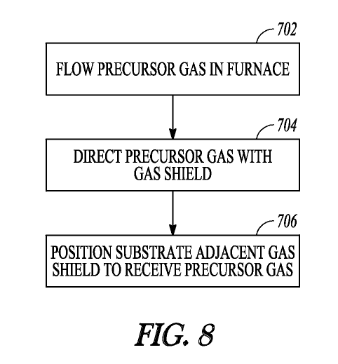

FIG. 8 illustrates a chemical vapor deposition method according to one example. The method can include flowing 802 a precursor gas in a hot walled furnace, directing 804 the precursor gas with a gas shield having a conical portion with a plurality of holes therethrough, and positioning 806 a substrate adjacent the conical portion of the gas shield to receive the precursor gas passing through the plurality of holes. According to one example of the method, the substrate can comprise a reticulated carbon foam having a porosity of between 55% and 90%. According to one example of the method, the precursor gas can include a tantalum or tantalum alloy. Additionally, in some instances a total area of the plurality of holes can be between about 10% to about 40% of a surface area of the conical portion. In further examples, the plurality of holes can be arranged as concentric rings about a tip of the conical portion.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls. In this document, the terms “a” or “an” are used, as is common in patent documents, to include one or more than one, independent of any other instances or usages of “at least one” or “one or more.” In this document, the term “or” is used to refer to a nonexclusive or, such that “A or ” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A gas shield for use in a chemical vapor deposition process, the shield comprising:
a ring portion adapted to receive a substrate; and
a conical portion coupled to the ring portion and having a plurality of holes therethrough that are configured to allow a precursor gas to communicate with the substrate.

2. The gas shield of claim 1, wherein the substrate comprises a reticulated carbon foam.

3. The gas shield of claim 1, wherein each hole of the plurality of holes has an area of between about 0.02% and about 0.3% of a surface area of the conical portion of the gas shield.

4. The gas shield of claim 1, wherein a total area of the plurality of holes is between about 10% and about 40% of a surface area of the conical portion.

5. The gas shield of claim 1, wherein the conical portion has an angle relative to a plane extending along an axial end of the ring portion of between about 7.5° and about 70°.

6. The gas shield of claim 1, wherein the plurality of holes are arranged as concentric rings about a solid tip region of the conical portion.

7. The gas shield of claim 1, wherein both the ring portion and the conical portion comprise graphite and both the ring portion and the conical portion have a wall thickness of less than 1 inch.

8. An assembly for use in a chemical vapor deposition process, the assembly comprising:
a furnace adapted to receive a precursor gas therein;
a gas shield disposed within the furnace in a flow path of the precursor gas, the gas shield having a conical portion configured to direct the precursor gas along an outer surface thereof and having a plurality of holes therethrough that are configured to allow the precursor gas to enter an inner cavity defined by the conical portion; and
a substrate disposed adjacent the conical portion and communicating with the inner cavity, wherein the substrate is configured to receive a thin film deposition from the precursor gas.

9. The assembly of claim 8, wherein the gas shield has a ring portion coupled to the conical portion and adapted to receive the substrate.

10. The assembly of claim 8, wherein the substrate comprises a reticulated carbon foam.

11. The assembly of claim 8, wherein the precursor gas includes a tantalum or tantalum alloy.

12. The assembly of claim 8, wherein each hole of the plurality of holes has an area of between about 0.025% and about 0.3% of a surface area of the conical portion of the gas shield.

13. The assembly of claim 8, wherein a total area of the plurality of holes is between about 10% and about 40% of a surface area of the conical portion.

14. The assembly of claim 8, wherein the conical portion has an angle relative to a plane extending along an axial end of the ring portion of between about 7.5° and about 70°.

15. The assembly of claim 8, wherein the plurality of holes are arranged as concentric rings about a solid tip region of the conical portion.

16. A chemical vapor deposition method, the method comprising:
flowing a precursor gas in a hot walled furnace;
directing the precursor gas with a gas shield having a conical portion with a plurality of holes therethrough; and
positioning a substrate adjacent the conical portion of the gas shield to receive the precursor gas passing through the plurality of holes.

17. The method of claim 16, wherein the substrate comprises a reticulated carbon foam having a porosity of between 55% and 90%.

18. The method of claim 16, wherein the precursor gas includes a tantalum or tantalum alloy.

19. The method of claim 16, wherein a total area of the plurality of holes is between about 10% and about 40% of a surface area of the conical portion.

20. The method of claim 16, wherein the plurality of holes are arranged as concentric rings about a tip of the conical portion.
